(19) United States
(12) Patent Application Publication
(10) Pub. No.: US 2019/0326389 A1
(43) Pub. Date: Oct. 24, 2019

(54) Method Of Manufacturing A Deep Trench Super Junction MOSFET

(71) Applicant: Champion Microelectronic Corp., Hsinchu (TW)

(72) Inventors: Haiping Dun, Fremont, CA (US); Hung-Chen Lin, Hsinchu (TW); Chi-Wu Yao, Zhubei (TW)

(21) Appl. No.: 16/389,916

(22) Filed: Apr. 19, 2019

Related U.S. Application Data
(60) Provisional application No. 62/660,976, filed on Apr. 21, 2018.

(51) Int. Cl. H01L 29/06; H01L 29/66

(52) U.S. Cl. CPC H01L 29/0634; H01L 29/66477

(57) ABSTRACT

Methods for manufacturing a MOSFET device for high voltage application are disclosed to solve less-than-90-degree trench angle problem. In one embodiment, the trenches in a MOSFET device are filled with different concentrations of P− epitaxial material at different stages to improve charge balance. In an alternative embodiment, several N− epitaxial layers with different concentrations are created before etching trenches filled with P− epitaxial material. Yet in another embodiment, a reverse deep trench process creates a P− epitaxial layer first, and etches wider conductive regions to be filled with N− epitaxial later, leaving the remaining P− epitaxial columns as non-conductive regions similar to the traditional P− epitaxial trenches.

### CROSS REFERENCE

This application claims the benefit of U.S. Provisional Application with Ser. No. 62/660,976 filed on Apr. 21, 2018, the entire contents of which is hereby incorporated by reference as if fully set forth herein, under 35 U.S.C. § 119(e).

### FIELD OF INVENTION

This invention generally relates to semiconductor power device technology. More specifically, it is related to methods and structures for manufacturing a MOSFET device for high voltage application.

### DESCRIPTION OF THE RELATED ART

Super-junction MOSFET has the advantages of high breakdown voltage and high switching speed. FIG. 1 illustrates a typical super-junction MOSFET that has the structure of a N+ substrate 101, a N− epitaxial layer 103 and a trench or trenches 105 etched inside the N− epitaxial layer. The trenches 105 are filled with P− material to counter-balance the charges in the N− epitaxial layer 103. For high voltage application, the MOSFET device needs to have a deep N− epitaxial layer 103 and corresponding deep P− trenches 105. The increased depth of the device can increase the breakdown voltage, and the charge balancing effect of P− trenches 105 allows N− epitaxial layer 103 to increase its concentration, and hence lower the ON-resistance of the device to increase switching speed.

FIG. 2 illustrates a portion of the MOSFET device of FIG. 1 to further explain the details of its manufacturing process. In FIG. 2, the overall width of the Epi-layer 201 and the trench 203 of the MOS device is called “Pitch” 210. When the pitch becomes smaller, it will allow the concentration of N− epitaxial layer 201 to increase, which in turns leads to lower ON− resistance. The remaining N− epitaxial region 201 between the P− trench 203 is called “Island” 212, and acts as conductive region for the MOSFET device. The top part of P− trench 203 is called “Pillar” 214. The P− trench 203 is a dead space merely used to counter-balance the charges in the N− island 212.

In terms of the dimensions, the Island width 212 is larger than the Pillar width 214. The ratio between the Island width 212 and the Pillar width 214 should maintain a fixed ratio when the overall Pitch width 210 decrease to maintain the charge balance. For example, for a 13 um channel device, the ratio of Island width 212 to Pillar width 214 is about 7 um/6 um. For a 11 um channel device, the ratio of Island width 212 to Pillar width 214 is about 6 um/5 um.

Unfortunately, the current manufacturing equipment cannot create a perfect P− rectangular trench 203 with 90 degree angle between its trench wall 203a and trench bottom 203b (i.e. a perpendicular wall and bottom). Therefore, as shown in FIG. 2, the imperfect trench 203 has a slope or a smaller than 90 degree trench angle θ (measuring the outside wall of trench to a horizontal line or the bottom of the trench 203b) which undermines the charge-balancing effect, and hence affects the breakdown voltage and the ON-resistance.

Another prominent problem is that as the Pillar depth 203 increases and becomes deeper, this trench angle (θ) effect magnifies the charge-balancing problem because the area of P− trench 203 become smaller when it gets closer to its bottom. At the same time, the trench filling process becomes harder when the trench 203 becomes deeper. Therefore, there is a need to solve these problems.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY

Various embodiments of methods for manufacturing a super-junction MOSFET are contemplated. In one embodiment, a P− epitaxial layer is deposed on top of a N+ substrate layer. Three vertical trenches in rectangular shape are etched in the left, middle and right side of the P− epitaxial layer, then filled with N− type epitaxial semiconductor material with low diffusion property. The process of etching the trenches results in that the two remaining P− type columns have uniform width from its top to bottom, and are perpendicular to the N+ substrate layer. The N− type vertical trenches are used as conductive regions and the P− type columns are used for non-conductive regions.

In one embodiment, a N− epitaxial layer is deposed on top of a N+ substrate layer. Two vertical trenches are etched to the left and right of the N− epitaxial layer. The two vertical trenches are filled with different concentration of a P− epitaxial material through two or more stages.

In one embodiment, two or more N− epitaxial layer is deposed on top of a N+ substrate layer. Each N− epitaxial layer has different concentration but the concentration of those N− epitaxial layers become successively higher for the higher layers. Two vertical trenches are etched into the N− epitaxial layers and filled with a P− epitaxial material of uniform concentration.

These and other embodiments will become apparent upon reference to the following description and accompanying drawings.

### BRIEF DESCRIPTION OF THE DRAWINGS

The present invention is illustrated by way of example, and not by way of limitation in the figures of the accompanying drawings and in which like reference numerals refer to similar elements and in which:

FIG. 1 illustrates a cross-sectional view of a super-junction MOSFET.

FIG. 2 illustrates a portion of the MOSFET device of FIG. 1.

FIGS. 3A, 3B and 3C are cross-sectional view for use in illustration of the process of manufacturing a MOSFET device according to an embodiment.

FIGS. 4A and 4B are cross-sectional view for use in illustration of the process of manufacturing a MOSFET device according to a second embodiment.

FIGS. 4C and 4D are cross-sectional view for use in illustration of the process of manufacturing a MOSFET device according to a third embodiment.

FIGS. 5A, 5B, 5C and 5D are cross-sectional view for use in illustration of the Reverse Deep Trench Super-junction MOSFET process of manufacturing a MOSFET device according to a fourth embodiment.

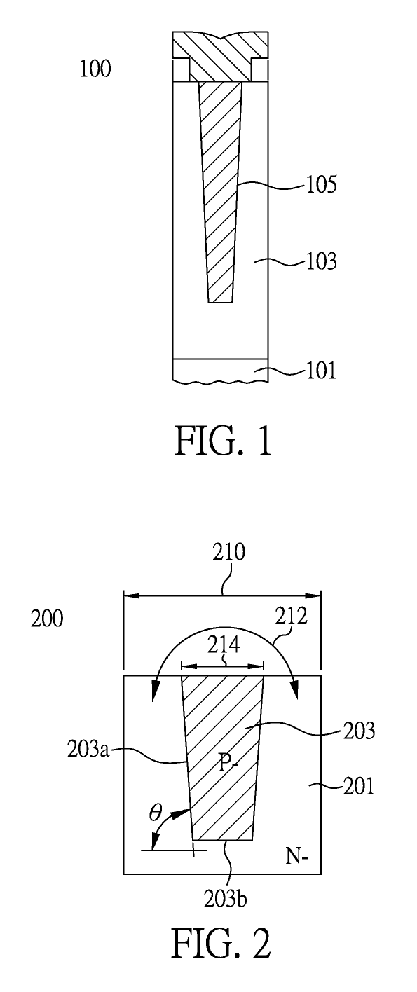

### DETAILED DESCRIPTION

In the following description, numerous specific details are set forth to provide a thorough understanding of the methods and mechanisms presented herein. However, one having ordinary skill in the art should recognize that the various embodiments may be practiced without these specific details. In some instances, well-known structures, components, signals, computer program instructions, and techniques have not been shown in detail to avoid obscuring the approaches described herein. It will be appreciated that for simplicity and clarity of illustration, elements shown in the figures have not necessarily been drawn to scale. For example, the dimensions of some of the elements may be exaggerated relative to other elements.

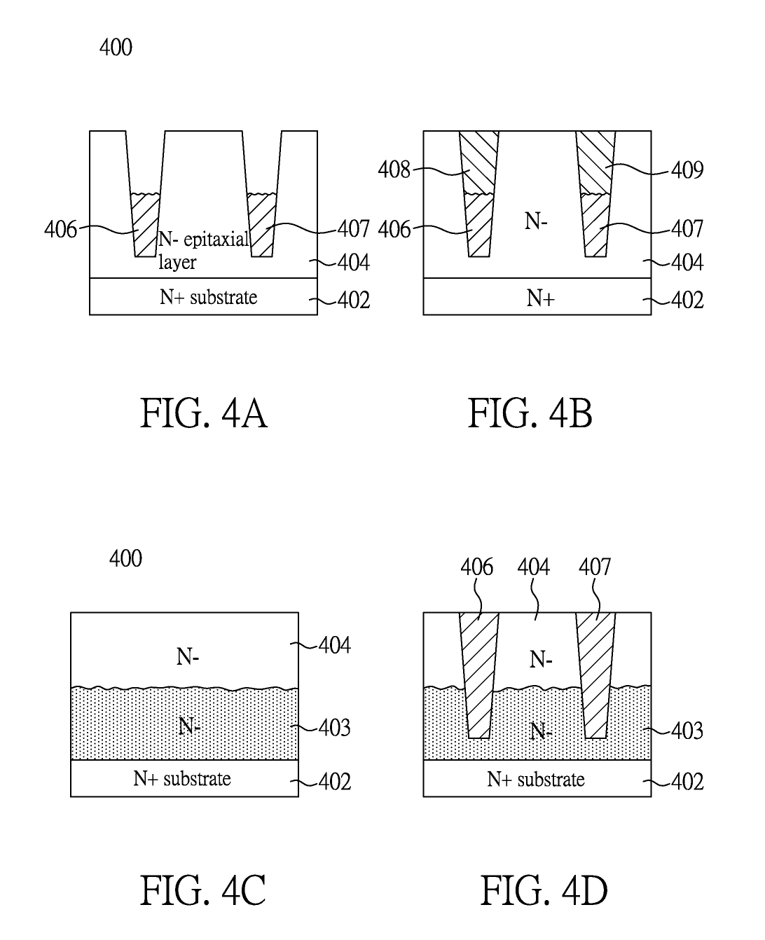

FIGS. 3A-3C illustrate a current manufacturing process of a Super-junction MOSFET device. As the first step, FIG. 3A has a N− epitaxial layer 304 above a N+ substrate layer 304. In step 2 shown in FIG. 3B, a deep trench 306 is etched on the left side of the N− epitaxial layer 304. Another deep trench 308 is etched on the right side of the N− epitaxial layer 304. These two trenches 306 & 308 should be deep and close to the bottom of the N− epitaxial layer 304 but not touch the N+ substrate 302. In Step 3 of FIG. 3C, the trenches 306 & 308 are filled with a P− epitaxial material, such as Boron. Step 4 (not shown) will add polysilicon, pwell and gate on top of the N− epitaxial layer 308 and P− trenches 306 & 308 to form a MOSFET device. Please note that the drawings are simplified to illustrate the manufacturing process, but the trench angle problem still exists as discussed above. Etching trenches as dead space and filling with P− epitaxial material for charge-counter balancing purpose is more straightforward because the trenches do not act as the conductive region of the device, so it has less concern about the quality of the trench filler.

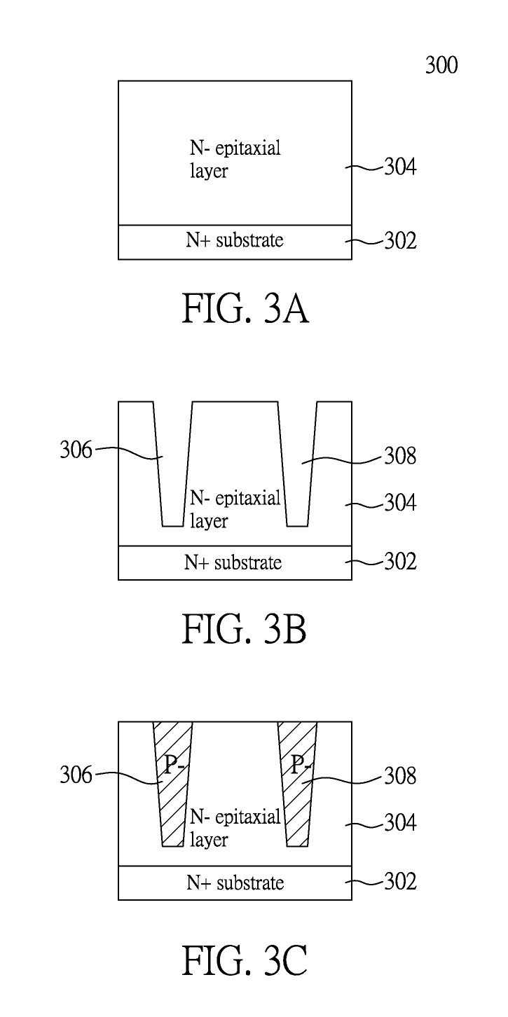

To solve the difficulty of etching trenches that creates the trench angle problem (θ as shown in FIG. 2) leading to ineffective charge-balance when the industry wants to reduce pitch width 210 while increase trench depth 203, improved manufacturing processes are proposed.

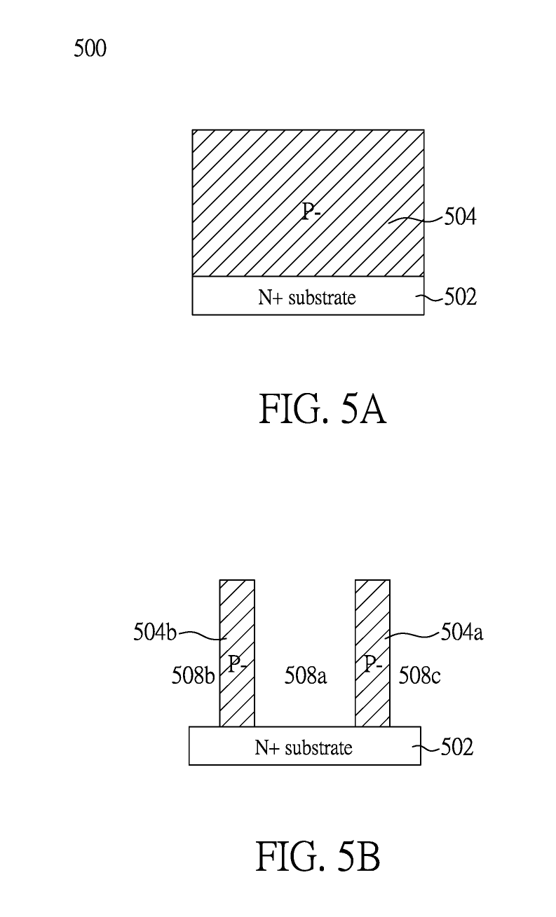

FIGS. 4A-4B illustrate a manufacturing process that involves two-stage trenching filling applicable to the structure similar to FIG. 3. In this approach, when filling the deep trenches 406 & 407 with P− epitaxial material as shown in FIG. 4A, the lower-half of the trenches 406 & 407 can be filled with higher concentration of a P− epitaxial material. Thereafter, in FIG. 4B, another P− epitaxial material with lower concentration completes the filling of the upper-half portion 408 & 409 of the same trenches. The N− epitaxial layer 404 has uniform concentration. Although FIGS. 4A-4B illustrate only two different concentrations of filling in the trenches, a manufacturing process of more stages with more than two different concentrations is possible to create a successively decreasing P− concentration as it goes up the trenches.

FIGS. 4C-4D illustrate an alternative manufacturing process. In this approach as shown in FIG. 4C, a N− epitaxial layer 403 is added above a N+ substrate 402. Next, another N− epitaxial layer 404 with higher concentration than that of the layer 403 is added above the N− epitaxial layer 403. In FIG. 4D, two trenches 406 and 407 are created with depth reaching the bottom of the N− epitaxial layer 403. As a result, the trenches 406 and 407 cross two different concentrations of N− epitaxial layer 403 and 404. Then, both trenches 406 and 407 are filled with P− epitaxial material with uniform concentration.

These approaches illustrated in FIGS. 4A-4D can achieve a better charge-balance result than the process illustrated in FIGS. 3A-3C even under the same imperfect rectangular trench shape with less-than-90-degree trench angle (θ) described in FIG. 2.

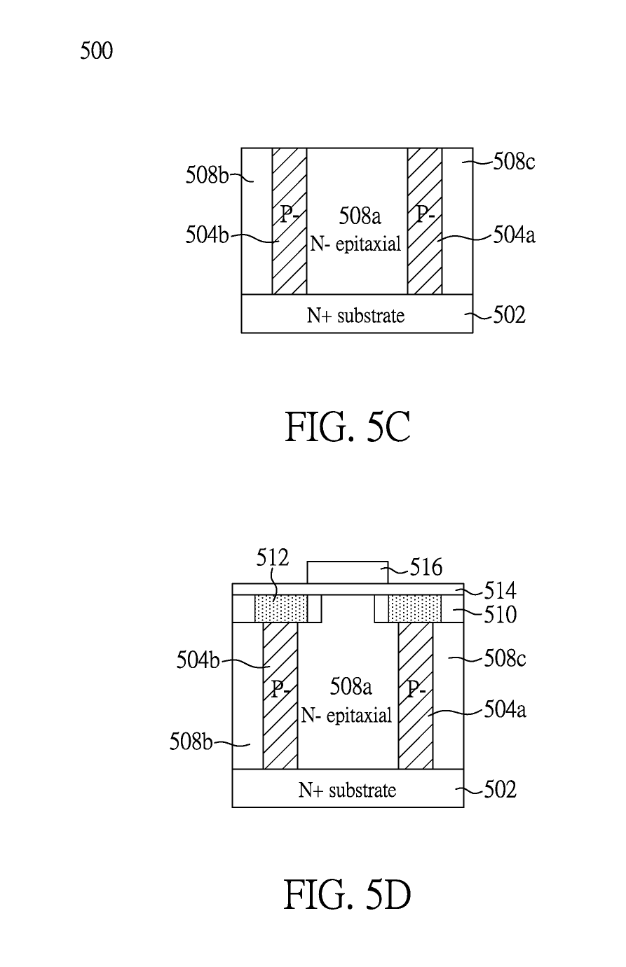

FIGS. 5A-5C illustrate yet another manufacturing process called Reverse Deep Trench Super-junction MOSFET process. This approach allows even deeper trenches and smaller pitch width than the earlier described approaches, and hence can create a much higher voltage Super-junction MOS operating at 1,000 V or higher.

In FIG. 5A, as the first step, a P− epitaxial layer 504 with uniform concentration is added above a N+ substrate layer 502. In step 2 of FIG. 5B, the device is etched with three rectangular trenches 508a (middle), 508b (left) and 508c (right) in the P− epitaxial layer 504 to result in two narrow P− epitaxial columns 504a and 504b. Although the left and right trenches 508b and 508c are called trenches, they can etch away the P− epitaxial material 504 to leave only two remaining P− epitaxial columns 504a and 504b. The drawings are simplified to illustrate the concept.

In FIG. 5B, the trenches 508a, 508b and 508c go all the way down to the bottom of P− epitaxial layer 504 and reach the N+ substrate 502. Step 3 in FIG. 5C fills the trenches 508a, 508b and 508c with N− epitaxial material, such as Arsenic (As) or Phosphorus (Phos), that has lower diffusion capability to minimize lateral dopant movement. As shown in FIG. 5C, each of the two narrow P− epitaxial columns 504a and 504b has uniform width from its top to bottom and thus resulting in a perpendicular position to the N+ substrate 502. From the perspective of FIG. 2 mentioned earlier, this is equivalent to two P− trenches (or pillars) 203 having 90 degree trench angles (θ) inside an N− epitaxial layer 201.

Steps 4 of FIG. 5D adds polysilicon 514, Pwells 510, gate 516 and N+ diffusion formation 512 on top of both P− epitaxial columns 504a and 504b and the N− epitaxial trenches 508a, 508b and 508c. Step 5 (not shown) finalizes the MOS device 500 by adding backend ILD, metal and passivation. This MOS device 500 still follows the device dimensions described in FIG. 2. Therefore, the width of the middle N− epitaxial trench 508a is larger than the width of each P− epitaxial column 504a and 504b. The widths of P− epitaxial column 504a and 504b are roughly equal. Furthermore, the “Island/Pillar” ratio of this device 500 resulting from this process should have a fixed relation as discussed above. In other words, the ratio of the width of the middle N− epitaxial trench 508a to the width of either one of the P− epitaxial columns 504a or 504b should be fixed. For example, for a 13 um channel device, the ratio is about 7/6. For a 11 um channel device, the ratio is about 6/5.

The N− epitaxial trenches 508a, 508b and 508c now act as the conductive region of the MOSFET device while the P− epitaxial columns 504a and 504b act as dead space. This approach takes an advantage of wider space between the two P− epitaxial columns 504a and 504b, and thus it's easier to achieve 90 degree trench angles than the traditional methods. However, in this approach, the quality of the filled N− epitaxial semiconductor material in trenches 508a, 508b and 508c, serving as a device layer, needs to be carefully maintained for quality control. Although the final complete MOS device looks similar to that of FIG. 3C, this approach achieves much better charge-balance effect and hence better device performance because both N regions (508a, 508b and 508c) and P regions (504a and 504b) have near perfect rectangular shapes.

What is claimed is:

1. A method of manufacturing a semiconductor MOS device, comprising:
creating a N+ substrate layer;
creating a P− epitaxial layer on top of the N+ substrate layer;
etching a first vertical trench in the middle of the device, from top of the P− epitaxial layer down to the top of N+ substrate layer;
etching a second vertical trench on left side of the first vertical trench, from top of the P− epitaxial layer down to the top of the N+ substrate layer, to form a first narrow column of a P− epitaxial material between the first vertical trench and the second vertical trench;
etching a third vertical trench on the right side of the first vertical trench, from top of the P− epitaxial layer down to the top of N+ substrate layer, to form a second narrow column of the P− epitaxial material between the first vertical trench and the third vertical trench; and
filling the first, second and third etched trenches with N− type epitaxial semiconductor material of low diffusion property which has lower concentration than that of the N+ substrate layer;
wherein the first etched vertical trench is a conductive region, and the first and second narrow P− columns are non-conductive regions.

2. The method of claim 1, wherein etching the first vertical trench and the second vertical trench resulting in the first narrow P− column having a uniform width from its top to its bottom.

3. The method of claim 2, wherein the first narrow P− column is perpendicular to the top surface of the N+ substrate.

4. The method of claim 1, wherein the width of the first vertical trench of N− type semiconductor material is wider than the width of either of the first or second narrow P− column.

5. The method of claim 1, wherein the width of the first narrow P− column is equal to the width of the second narrow P− column.

6. The method of claim 5, the ratio of the width of the first vertical trenche to the width of either the first or second narrow P− column is fixed during the manufacturing process.

7. A method of manufacturing a semiconductor MOS device, comprising:
creating a N+ substrate layer;
creating a P− epitaxial layer on top of the N+ substrate layer;
etching a first rectangular portion in the middle of the device, from top of the P− epitaxial layer down to the top of N+ substrate layer;
etching away a second rectangular portion of the P− epitaxial layer to the left of the first rectangular portion, resulting in a first narrow column of a P− epitaxial material, wherein the first narrow P− column has a uniform width from its top to its bottom; and
filling the first and second rectangular portions with N− type epitaxial semiconductor material of low diffusion property which has lower concentration than that of the N+ substrate layer;
wherein the first rectangular portion is a conductive region, and the first narrow P− column is a non-conductive region.

8. The method of claim 7, wherein the first narrow P− column is perpendicular to the top surface of N+ substrate.

9. The method of claim 7, wherein the width of the first rectangular portion is wider than the width of the first narrow P− column.

10. The method of claim 7, the ratio of the width of the first rectangular portion to the width of the first narrow P− column is fixed during the manufacturing process.

11. A method of manufacturing a semiconductor MOS device, comprising:
creating a N+ substrate layer;
creating a N− epitaxial layer on top of the N+ substrate layer;
etching a first vertical trench to the left the device, from top of the N− epitaxial layer down to the top of the N+ substrate layer;
etching a second vertical trench to the right the device, from top of the N− epitaxial layer down to the top of the N+ substrate layer;
filling the lower half of both the first vertical and second vertical trenches with a first P− epitaxial material; and
filling the upper half of both the first vertical and second vertical trenches with a second P− epitaxial material;
wherein the concentration of the first P− epitaxial material is different from the concentration of second P− epitaxial material;
wherein the N− epitaxial layer is a conductive region, and the first and second vertical trenches are non-conductive regions.

12. The method of claim 11, wherein the concentration of the first P− epitaxial material is higher than the concentration of the second P− epitaxial material.

13. The method of claim 11, wherein the distance between the first vertical trench and the second vertical trench is longer than the width of each of the first and second vertical trenches.
